(19) United States
(12) Patent Application Publication
(10) Pub. No.: US 2025/0308561 A1
(43) Pub. Date: Oct. 2, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Hongsoo KIM, Suwon-si (KR); Eunbi PARK, Suwon-si (KR); Minyoung YOO, Suwon-si (KR); Hose CHOI, Suwon-si (KR)

(73) Assignee: Samsung Electronics Co., Ltd., Suwon-si (KR)

(21) Appl. No.: 19/013,446

(22) Filed: Jan. 8, 2025

(30) Foreign Application Priority Data
Apr. 2, 2024 (KR) 10-2024-0044599

(51) Int. Cl. G11C 5/06; H01L 23/00; H01L 25/18; H10B 41/10; H10B 41/27; H10B 41/35; H10B 41/41; H10B 43/10; H10B 43/27; H10B 43/35; H10B 43/40; H10B 80/00; H10D 80/30

(52) U.S. Cl. CPC G11C 5/063; H01L 24/08; H01L 25/18; H10B 41/10; H10B 41/27; H10B 41/35; H10B 41/41; H10B 43/10; H10B 43/27; H10B 43/35; H10B 43/40; H10B 80/00; H10D 80/30; H01L 24/32; H01L 24/48; H01L 2224/08145; H01L 2224/32145; H01L 2224/32225; H01L 2224/48147; H01L 2224/48227; H01L 2225/06506; H01L 2225/0651; H01L 2225/06524; H01L 2225/06544; H01L 2225/06562; H01L 2924/1438

(57) ABSTRACT

A semiconductor device may include a semiconductor substrate including a cell array area, an extension area, and a pad area; a first stacked structure on the cell array area and the extension area, the first stacked structure including first conductive layers and first insulating layers alternately stacked; an input/output pad on an upper end portion of the pad area; a second stacked structure on a lower side of the input/output pad and including a plurality of second conductive layers and a plurality of second insulating layers alternately stacked on the pad area; a plurality of through wiring structures respectively connected to the plurality of second conductive layers on the pad area; and a mold insulator between the input/output pad and the second stacked structure such that the input/output pad and the second stacked structure may be vertically spaced apart from each other.

### CROSS-REFERENCE TO RELATED APPLICATION

This application claims the benefit of Korean Patent Application No. 10-2024-0044599 filed on Apr. 2, 2024, in the Korean Intellectual Property Office, the entire disclosure of which is incorporated herein by reference for all purposes.

### BACKGROUND

### 1. Field

Various embodiments of the disclosure relate to a semiconductor device and an electronic system including the same.

### 2. Description of the Related Art

There is a demand for a semiconductor device capable of storing a large amount of data in an electronic system that requires data storage. Therefore, methods to increase the data storage capacity of a semiconductor device have been studied. For example, one of the methods to increase the data storage capacity of a semiconductor device proposes a semiconductor device including three-dimensionally arranged memory cells instead of two-dimensionally arranged memory cells.

The above information may be presented as the related art to help with the understanding of the disclosure. No arguments or decisions are made as to whether any of the above is applicable as a prior art related to the disclosure.

### SUMMARY

In an embodiment, a semiconductor device may include a semiconductor substrate including a cell array area, an extension area, and a pad area; a first stacked structure on the cell array area and the extension area, the first stacked structure including a plurality of first conductive layers and a plurality of first insulating layers that are alternately stacked; an input/output pad on an upper end portion of the pad area; a second stacked structure on a lower side of the input/output pad, the second stacked structure including a plurality of second conductive layers and a plurality of second insulating layers alternately stacked on the pad area; a plurality of through wiring structures respectively connected to the plurality of second conductive layers on the pad area; and a mold insulator between the input/output pad and the second stacked structure such that the input/output pad and the second stacked structure are vertically spaced apart from each other.

According to an embodiment, it is possible to improve the space efficiency of the semiconductor device by forming the second stacked structure and the plurality of through wiring structures in a space below the input/output pad and utilizing the second stacked structure and the plurality of through wiring structures as capacitors, resistors, and/or wires.

According to an embodiment, since the second stacked structure and/or the plurality of through wiring structures are vertically spaced spart from the input/output pad, it is possible to reduce damage to the second stacked structure and/or the plurality of through wiring structures in the process of connecting a test electrode and/or a connection structure to the input/output pad.

In an embodiment, an upper end of the second stacked structure may be lower than an upper end of the first stacked structure.

In an embodiment, the second stacked structure and the plurality of through wiring structures may be configured to function as at least one of capacitors, resistors, or connection wires.

In an embodiment, the plurality of through wiring structures may include a first through wiring structure connected to a first one of the plurality of second conductive layers, and a second through wiring structure connected to a second one of the plurality of second conductive layers.

In an embodiment, a single capacitor may include the first one of the plurality of second conductive layers, the second one of the plurality of second conductive layers, and one of the plurality of second insulating layers therebetween.

In an embodiment, one or more of the plurality of second conductive layers and two or more of the plurality of second insulating layers may be between the first one of the plurality of second conductive layers and the second one of the plurality of second conductive layers, the one or more of the plurality of second conductive layers and the second one of the plurality of second conductive layers may be configured so that electricity does not flow therethrough, and the first one of the plurality of second conductive layers, the second one of the plurality of second conductive layers, and the one or more of the plurality of the second conductive layers and the two or more second insulating layers are configured to function as a single capacitor.

In an embodiment, the first through wiring structure and the second through wiring structure may be alternately arranged in a horizontal direction.

In an embodiment, the plurality of through wiring structures may further include: a first through wiring structure connected to a first one of the plurality of second conductive layers; and a second through wiring structure connected to a second one of the plurality of second conductive layers. The first one of the plurality of second conductive layers may be configured to function as a resistor or a connection wire.

In an embodiment, a connection structure may be connected to the input/output pad. The connection structure may be configured for being electrically connected to a package substrate.

In an embodiment, the first conductive layers may be used as word lines or bit lines.

In an embodiment, the first stacked structure and the second stacked structure may be manufactured simultaneously by a same process.

In an embodiment, the semiconductor device may include a cell array structure including the first stacked structure and the second stacked structure, and a peripheral circuit structure positioned at a lower end of the cell array structure and electrically connected to the cell array structure through a bonding pad.

In an embodiment, the input/output pad may be positioned at an upper end of the cell array structure.

In an embodiment, the semiconductor device may further include an input/output contact structure penetrating the cell array structure. The input/output contact structure may electrically connect the input/output pad and the peripheral circuit structure.

In an embodiment, the semiconductor device may further include a plurality of channel structures penetrating the first stacked structure in the cell array area, and a plurality of cell contact plugs respectively connected to the plurality of first conductive layers in the extension area.

In an embodiment, an electronic system may include a package substrate; a semiconductor device on the package substrate; and a connection structure electrically connecting the package substrate and the semiconductor device. The semiconductor device may include a semiconductor substrate including a cell array area, an extension area, and a pad area, a first stacked structure on the cell array area and the extension area, the first stacked structure including a plurality of first conductive layers and a plurality of first insulating layers that are alternately stacked, an input/output pad on an upper end portion of the pad area and electrically connected to the package substrate through the connection structure, a second stacked structure on a lower side of the input/output pad, the second stacked structure including a plurality of second conductive layers and a plurality of second insulating layers alternately stacked, a plurality of through wiring structures respectively connected to the plurality of second conductive layers on the pad area, and a mold insulator between the input/output pad and the second stacked structure such that the input/output pad and the second stacked structure are vertically spaced apart from each other.

In an embodiment, an upper end of the second stacked structure may be positioned lower than an upper end of the first stacked structure.

In an embodiment, the second stacked structure and the plurality of through wiring structures may be configured to function as at least one of capacitors, resistors, or connection wires.

In an embodiment, the first conductive layers may be used as word lines or bit lines.

In an embodiment, the first stacked structure and the second stacked structure may be manufactured simultaneously by a same process.

The effects of the semiconductor device and the electronic system including the same according to various embodiments may not be limited to the above-mentioned effects, and other unmentioned effects may be clearly understood from the following description by one of ordinary skill in the art.

### BRIEF DESCRIPTION OF THE DRAWINGS

The foregoing and other aspects, features, and advantages of certain embodiments in the disclosure will become apparent from the following detailed description with reference to the accompanying drawings.

FIG. 1 is a diagram schematically illustrating an electronic system including a semiconductor memory device according to an example embodiment of the disclosure.

FIG. 2 is a perspective view schematically illustrating an electronic system including a semiconductor memory device according to an embodiment of the disclosure.

FIGS. 3 and 4 are cross-sectional views schematically illustrating semiconductor packages according to an embodiment.

FIG. 5 is a schematic cross-sectional view of a semiconductor device according to an embodiment.

FIG. 6 is a schematic cross-sectional view of a pad area of a semiconductor device according to an embodiment.

FIG. 7 is a schematic plan view illustrating an arrangement of a plurality of through wiring structures in a pad area of a semiconductor device according to an embodiment.

FIG. 8 is a schematic cross-sectional view of a pad area of a semiconductor device according to an embodiment.

FIG. 9 is a schematic cross-sectional view of a pad area of a semiconductor device according to an embodiment.

FIG. 10 is a schematic cross-sectional view of a semiconductor device according to an embodiment.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, embodiments will be described in detail with reference to the accompanying drawings. When describing the embodiments with reference to the accompanying drawings, like reference numerals refer to like components, and any repeated description related thereto will be omitted.

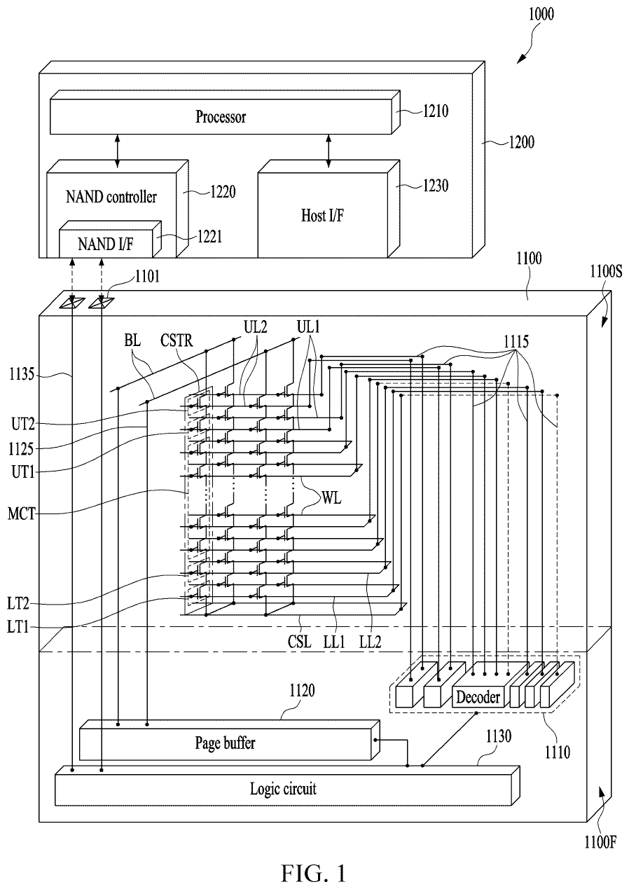

FIG. 1 is a diagram schematically illustrating an electronic system including a semiconductor memory device according to an example embodiment of the disclosure.

Referring to FIG. 1, in an embodiment, an electronic system 1000 may include a semiconductor memory device 1100 and a controller 1200 electrically connected to the semiconductor memory device 1100. The electronic system 1000 may be a storage device that includes a single or a plurality of semiconductor memory devices 1100 or may be an electronic device that includes the storage device. For example, the electronic system 1000 may be a solid-state drive (SSD) device, a Universal Serial Bus (USB), a computing system, a medical device, or a communication device, each of which includes a single or a plurality of semiconductor memory devices 1100.

In an embodiment, the semiconductor memory device 1100 may be a nonvolatile memory device, such as a NAND flash memory device. The semiconductor memory device 1100 may include a first structure 1100F and a second structure 1100S on the first structure 1100F. In an embodiment, the first structure 1100F may be arranged next to the second structure 1100S.

In an embodiment, the first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In an embodiment, in the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may vary according to embodiments.

In an embodiment, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In an embodiment, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. At least one of the lower erase control transistor LT1 and the upper erase control transistor UT2 may be used for an erasure operation of deleting data stored in the memory cell transistors MCT using a gate induced drain leakage (GIDL) phenomenon.

In an embodiment, the common source line CSL, the first and second gate lower lines LL1 and LL2, the word lines WL, and the first and second gate upper lines UL1 and UL2 may be electrically connected to the decoder circuit 1110 through first connection wires 1115 that extend from the first structure 1100F to the second structure 1100S. The bit lines BL may be electrically connected to the page buffer 1120 through second connection wires 1125 that extend from the first structure 1100F to the second structure 1100S.

In an embodiment, in the first structure 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 through an input/output connection wire 1135 that extends from the first structure 1100F to the second structure 1100S.

In an embodiment, although not shown in the drawings, the first structure 1100F may include a voltage generator (not shown). The voltage generator may generate a program voltage, a read voltage, a pass voltage, and a verification voltage required for the operation of the memory cell strings CSTR. Here, the program voltage may be a relatively high voltage (e.g., 20 volts (V) to 40 V) compared to the read voltage, the pass voltage, and the verification voltage.

In an embodiment, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as the program voltage applied to the word lines WL in a program operation. The page buffer 1120 may also include high-voltage transistors capable of withstanding high voltages.

In an embodiment, the controller 1200 may include a processor 1210, a NAND controller 1220, and a host interface 1230. In an embodiment, the electronic system 1000 may include a plurality of semiconductor memory devices 1100, and in this case, the controller 1200 may control the plurality of semiconductor memory devices 1100.

In an embodiment, the processor 1210 may control the overall operation of the electronic system 1000 including the controller 1200. The processor 1210 may operate based on predetermined firmware, and may control the NAND controller 1220 to access the semiconductor memory device 1100. The NAND controller 1220 may include a NAND interface 1221 that processes communication with the semiconductor memory device 1100. Through the NAND interface 1221, a control command to control the semiconductor memory device 1100, data to be written to the memory cell transistors MCT of the semiconductor memory device 1100, and/or data to be read from the memory cell transistors MCT of the semiconductor memory device 1100 may be transmitted. The host interface 1230 may provide a communication function between the electronic system 1000 and an external host. When a control command is received through the host interface 1230 from an external host, the processor 1210 may control the semiconductor memory device 1100 in response to the control command.

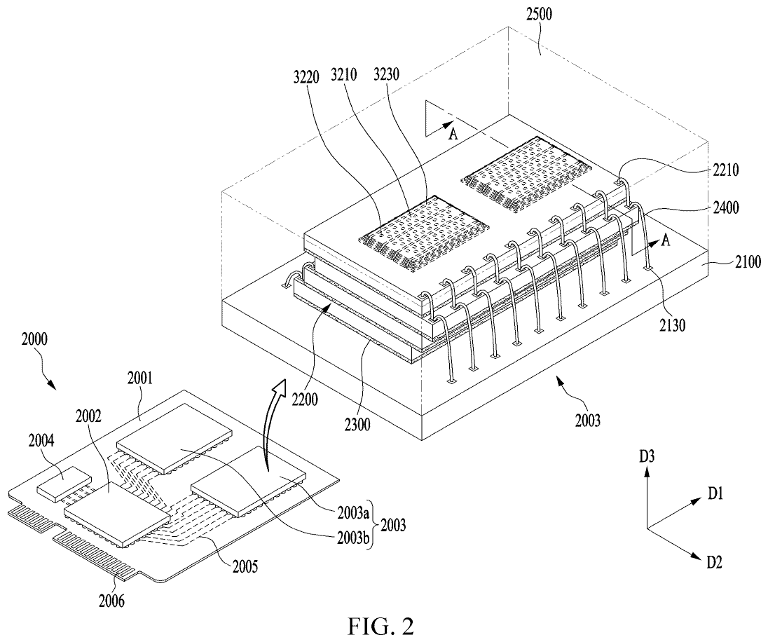

FIG. 2 is a perspective view schematically illustrating an electronic system including a semiconductor memory device according to an embodiment of the disclosure.

Referring to FIG. 2, in an embodiment, an electronic system 2000 may include a main board 2001, a controller 2002 mounted on the main board 2001, one or more semiconductor packages 2003, and a dynamic random-access memory (DRAM) 2004. The semiconductor packages 2003 and the DRAM 2004 may be connected to the controller 2002 through wiring patterns 2005 formed on the main board 2001.

In an embodiment, the main board 2001 may include a connector 2006 including a plurality of pins that are coupled to an external host. The number and arrangement of pins on the connector 2006 may vary based on a communication interface between the electronic system 2000 and the external host. In an embodiment, the electronic system 2000 may communicate with the external host according to any one of the interfaces, for example, Universal Serial Bus (USB), Peripheral Component Interconnect Express (PCI Express), Serial Advanced Technology Attachment (SATA), and M-PHY for Universal Flash Storage (UFS). In an embodiment, the electronic system 2000 may operate with the power supplied through the connector 2006 from the external host. The electronic system 2000 may further include a power management integrated circuit (PMIC) to distribute the power supplied from the external host to the controller 2002 and the semiconductor packages 2003.

In an embodiment, the controller 2002 may write data to the semiconductor packages 2003 or read data from the semiconductor packages 2003, thereby increasing the operating speed of the electronic system 2000.

In an embodiment, the DRAM 2004 may be a buffer memory to reduce the speed difference between the external host and the semiconductor packages 2003 that serve as data storage spaces. The DRAM 2004 included in the electronic system 2000 may operate as a kind of cache memory, and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

In an embodiment, the semiconductor packages 2003 may include first and second semiconductor packages 2003a and 2003b that are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, a connection structure 2400 that electrically connects the semiconductor chips 2200 to the package substrate 2100, and a molding layer 2500 that lies on the package substrate 2100 and covers the semiconductor chips 2200 and the connection structure 2400.

In an embodiment, the package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacked structures 3210 and channel structures 3220. Each of the semiconductor chips 2200 may include a semiconductor device according to an embodiment described below.

In an embodiment, the connection structure 2400 may be a bonding wire that electrically connects the input/output pad 2210 and the upper pads 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. In an embodiment, in each of the first and second semiconductor packages 2003a and 2003b, the semiconductor chips 2200 may be electrically connected to each other through connection structures including through-silicon vias (TSVs) instead of the connection structures 2400 based on the bonding wire manner.

In an embodiment, the controller 2002 and the semiconductor chips 2200 may be included in a single package. In an embodiment, the controller 2002 and the semiconductor chips 2200 may be mounted on a separate interposer substrate other than the main board 2001, and the controller 2002 and the semiconductor chips 2200 may be connected to each other through wires formed on the interposer substrate.

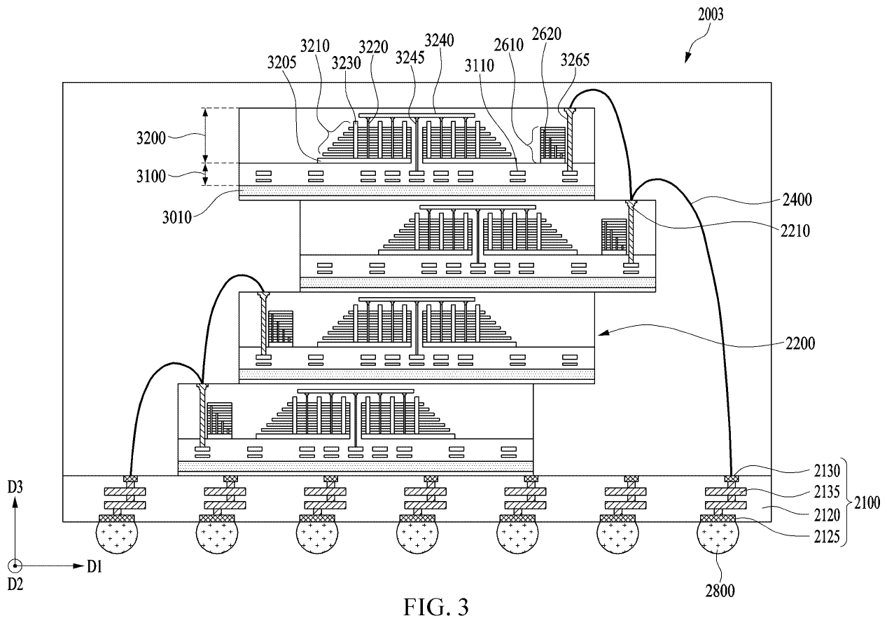

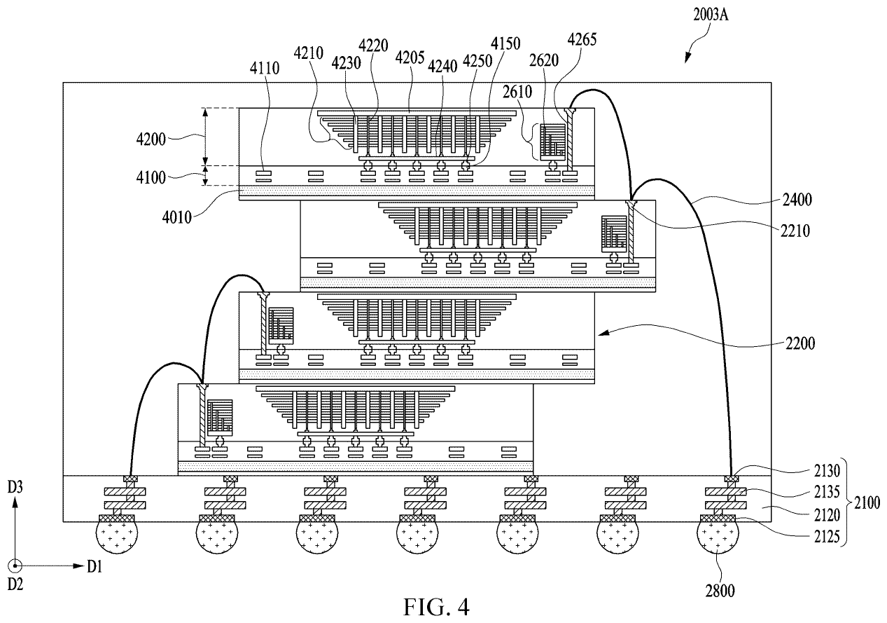

FIGS. 3 and 4 are cross-sectional views schematically illustrating semiconductor packages according to an embodiment. FIGS. 3 and 4 each depict an embodiment of a semiconductor package of FIG. 2 and conceptually show a section of the semiconductor package of FIG. 2, taken along line A-A.

Referring to FIG. 3, in an embodiment, in a semiconductor package 2003, the package substrate 2100 may be a printed circuit board. The package substrate 2100 may include a package substrate body 2120, upper pads 2130 disposed on a top surface of the package substrate body 2120, lower pads 2125 disposed on or exposed through a bottom surface of the package substrate body 2120, and internal wires 2135 electrically connecting the upper pads 2130 and the lower pads 2125 in the package substrate body 2120. The upper pads 2130 may be electrically connected to the connection structures 2400. The lower pads 2125 may be connected through conductive connectors 2800 to the wiring patterns 2005 in the main board 2001 of the electronic system 2000 as illustrated in FIG. 2.

In an embodiment, each of the semiconductor chips 2200 may include a semiconductor substrate 3010, and a first structure 3100 and a second structure 3200 that are sequentially stacked on the semiconductor substrate 3010. The first structure 3100 may include a peripheral circuit area including peripheral wires 3110. The second structure 3200 may include a source structure 3205, a stacked structure 3210 on the source structure 3205, channel structures 3220 and separation structures 3230 (e.g., separation structures 3230 of FIG. 2) that penetrate the stacked structure 3210, bit lines 3240 electrically connected to the channel structures 3220, and cell contact plugs electrically connected to word lines (e.g., the word lines WL of FIG. 1) of the stacked structure 3210.

In an embodiment, each of the semiconductor chips 2200 may include a through wire 3245 that is electrically connected to the peripheral wires 3110 of the first structure 3100 and extends into the second structure 3200. The through wire 3245 may be disposed on the outer side of the stacked structure 3210 and may further be disposed to penetrate the stacked structure 3210. Each of the semiconductor chips 2200 may further include an input/output connection wire 3265 that is electrically connected to the peripheral wires 3110 of the first structure 3100 and extends into the second structure 3200 and an input/output pad 2210 (e.g., the input/output pad 2210 of FIG. 2) that is electrically connected to the input/output connection wire 3265.

Referring to FIG. 4, in an embodiment, in a semiconductor package 2003A, each of the semiconductor chips 2200 may include a semiconductor substrate 4010, a first structure 4100 on the semiconductor substrate 4010, and a second structure 4200 bonded to the first structure 4100 in a wafer bonding manner on the first structure 4100.

In an embodiment, the first structure 4100 may include a peripheral circuit area including peripheral wires 4110 and first bonding structures 4150. The second structure 4200 may include a source structure 4205, a stacked structure 4210 between the source structure 4205 and the first structure 4100, channel structures 4220 and separation structures 4230 that penetrate the stacked structure 4210, and second bonding structures 4250 that are respectively electrically connected to the channel structures 4220 and word lines (e.g., the word lines WL of FIG. 1) of the stacked structure 4210. For example, the second bonding structures 4250 may be electrically connected to the channel structures 4220 and the word lines (e.g., the word lines WL of FIG. 1) respectively, through bit lines 4240 electrically connected to the channel structures 4220 and through cell contact plugs electrically connected to the word lines (e.g., the word lines WL of FIG. 1). The first bonding structures 4150 of the first structure 4100 and the second bonding structures 4250 of the second structure 4200 may be bonded to each other while being in contact with each other. Bonding portions of the first bonding structures 4150 and the second bonding structures 4250 may be formed of, for example, copper (Cu). Each of the semiconductor chips 2200 may further include an input/output connection wire 4265 that is electrically connected to the peripheral wires 4110 of the first structure 4100 and extends into the second structure 4200 and an input/output pad 2210 (e.g., the input/output pad 2210 of FIG. 2) that is electrically connected to the input/output connection wire 4265.

In an embodiment, the semiconductor chips 2200 of FIG. 3 or the semiconductor chips 2200 of FIG. 4 may be electrically connected to each other by connection structures 2400 in the form of bonding wires. In an embodiment, the semiconductor chips 2200 in one semiconductor package including the semiconductor chips 2200 of FIG. 3 or the semiconductor chips 2200 of 4 may be electrically connected to each other through connection structures including TSVs.

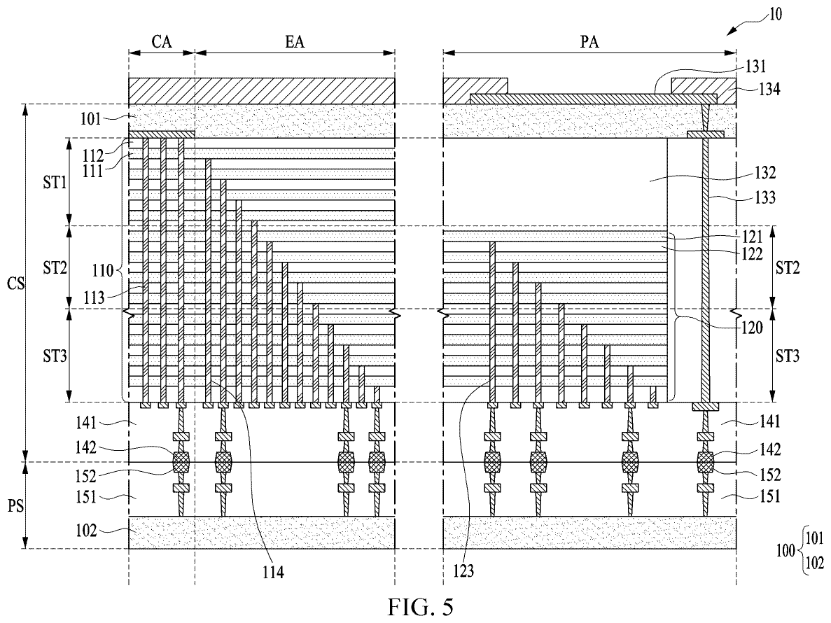

In an embodiment, a stacked structure 2610 and a through wiring structure 2620 penetrating the stacked structure 2610 may be positioned near a lower side of the input/output pad 2210 in FIGS. 3 and 4. The first structure 3100 of FIG. 3 and the first structure 4100 of FIG. 4 may correspond to a peripheral circuit structure (e.g., a peripheral circuit structure PS of FIG. 5) in the embodiment described below, and the second structure 3200 of FIG. 3 and the second structure 4200 of FIG. 4 may correspond to a cell array structure (e.g., a cell array structure CS of FIG. 5) in the embodiment described below. The stacked structures 2610 of FIGS. 3 and 4 may correspond to a second stacked structure (e.g., a second stacked structure 120 of FIG. 5) in the embodiment described below, and the through wiring structures 2620 of FIGS. 3 and 4 may correspond to a through wiring structure (e.g., a through wiring structure 123 of FIG. 5) in the embodiment described below.

FIG. 5 is a schematic cross-sectional view of a semiconductor device according to an embodiment. FIG. 5 is schematically illustrated for ease of description and does not limit the structure of a semiconductor device 10.

Referring to FIG. 5, the semiconductor device 10 according to an embodiment may include a semiconductor substrate 100, a first stacked structure 110, channel structures 113, cell contact plugs 114, a second stacked structure 120, through wiring structures 123, an input/output pad 131, a mold insulator 132, an input/output contact structure 133, and a top insulating layer 134. For example, the semiconductor device 10 may be a vertical NAND flash memory device and/or a DRAM. However, these are merely examples, and the type of semiconductor device 10 is not limited thereto.

In an embodiment, the semiconductor substrate 100 (e.g., the semiconductor substrate 3010 of FIG. 3 and/or the semiconductor substrate 4010 of FIG. 4) may include a cell array area CA, an extension area EA, and a pad area PA. The cell array area CA may be an area where a cell array is formed. For example, the plurality of channel structures 113 may be formed in the cell array area CA. The extension area EA may be positioned outside the cell array area CA. For example, the extension area EA may be arranged to surround the cell array area CA from the outside. For example, the plurality of cell contact plugs 114 to be electrically connected to a plurality of cell gate electrodes (e.g., first conductive layers 111), respectively, may be formed in the extension area EA. The pad area PA may be positioned outside the extension area EA. For example, the input/output pad 131 may be positioned in the pad area PA. The pad area PA may be an area for connecting the semiconductor device 10 to an external package substrate (e.g., the package substrate 2100 of FIG. 3 and/or the package substrate 2100 of FIG. 4). For example, the semiconductor substrate 100 may include a first semiconductor substrate 101 and a second semiconductor substrate 102. For example, the first semiconductor substrate 101, a substrate included in the cell array structure CS, may be positioned in an upper portion of the semiconductor device 10. For example, a source structure (e.g., a source structure 4205 of FIG. 4) may be positioned on the first semiconductor substrate 101. For example, the second semiconductor substrate 102, a substrate included in the peripheral circuit structure PS, may be positioned in a lower portion of the semiconductor device 10. For example, a decoder circuit (e.g., the decoder circuit 1110 of FIG. 1), a page buffer (e.g., the page buffer 1120 of FIG. 1), and a logic circuit (e.g., the logic circuit 1130 of FIG. 1) may be positioned on the second semiconductor substrate 102.

In an embodiment, the first stacked structure 110 (e.g., the stacked structure 3210 of FIG. 3 and/or the stacked structure 4210 of FIG. 4) may be positioned in the cell array area CA and the extension area EA. The first stacked structure 110 may include a plurality of first conductive layers 111 and a plurality of first insulating layers 112 that are alternately stacked in the vertical direction. For example, the plurality of first conductive layers 111 and the plurality of first insulating layers 112 may extend in the horizontal direction. The first conductive layers 111 may include a conductive material. For example, the first conductive layers 111 may include at least any one of a doped semiconductor (e.g., doped silicon), a conductive metal (e.g., tungsten, copper, molybdenum, and/or aluminum), a conductive metal nitride (e.g., titanium nitride and/or tantalum nitride), or a transition metal (e.g. titanium and/or tantalum). However, these are merely examples, and the material of the first conductive layers 111 is not limited thereto. The plurality of first conductive layers 111 may be used as the word lines WL, the gate upper lines UL1 and UL2, and/or the gate lower lines LL1 and LL2 described in FIG. 1. Alternatively, the plurality of first conductive layers 111 may be used as the bit lines BL described in FIG. 1. Each of the plurality of first insulating layers 112 may be positioned between two adjacent first conductive layers 111. The first insulating layers 112 may include an insulating material. For example, the first insulating layers 112 may include at least any one of silicon oxide, silicon nitride, or silicon oxynitride. However, these are merely examples, and the material of the first insulating layers 112 is not limited thereto. For example, the first stacked structure 110 may include a plurality of cell stacks ST1, ST2, and ST3 that are vertically stacked. Each of the cell stacks ST1, ST2, and ST3 included in the first stacked structure 110 may include a plurality of first conductive layers 111 and a plurality of first insulating layers 112. Each of the cell stacks ST1, ST2, and ST3 may be understood as a portion manufactured by a set of processes.

In an embodiment, the plurality of channel structures 113 may penetrate the first stacked structure 110 in the cell array area CA. The plurality of cell contact plugs 114 may be electrically connected to the plurality of first conductive layers 111, respectively, in the extension area EA. For example, each of the cell contact plugs 114 may penetrate at least a portion of the first stacked structure 110 to the height of a corresponding first conductive layer 111. For example, the plurality of cell contact plugs 114 may penetrate at least a portion of the first stacked structure 110 while forming a staircase shape. For example, based on FIG. 5, the plurality of cell contact plugs 114 may penetrate at least a portion of the first stacked structure 110 upward from the lower end of the first stacked structure 110. However, this is merely an example, and the plurality of cell contact plugs 114 may penetrate at least a portion of the first stacked structure 110 downward from the upper end of the first stacked structure 110. However, these are merely examples, and the structure of the plurality of channel structures 113 and/or the structure of the cell contact plugs 114 are not limited thereto.

In an embodiment, the input/output pad 131 (e.g., the input/output pad 2210 of FIG. 3 and/or the input/output pad 2210 of FIG. 4) may be positioned in the upper end portion of the pad area PA. For example, the input/output pad 131 may be positioned at the upper end portion of the cell array structure CS (e.g., the upper end portion of the first semiconductor substrate 101) in the pad area PA. A connection structure (e.g., the connection structure 2400 of FIG. 3 and the connection structure 2400 of FIG. 4) to be electrically connected to a package substrate (e.g., the package substrate 2100 of FIG. 3 and/or the package substrate 2100 of FIG. 4) may be connected to the input/output pad 131. The top insulating layer 134 may cover at least a portion of the input/output pad 131. For example, the top insulating layer 134 may be configured to cover the upper end portion of the cell array structure CS (e.g., the upper end portion of the first semiconductor substrate 101). The input/output pad 131 may be exposed to the outside through an area where the top insulating layer 134 is removed. The input/output contact structure 133 may penetrate the cell array structure CS to electrically connect the input/output pad 131 and the peripheral circuit structure PS (e.g., the second semiconductor substrate 102) to each other. For example, the input/output contact structure 133 may vertically penetrate the cell array structure CS in the pad area PA. Meanwhile, the structure of the input/output contact structure 133 shown in the drawings is merely an example, and the structure of the input/output contact structure 133 is not limited thereto. For example, the input/output contact structure 133 may be configured to penetrate the second stacked structure 120.

In an embodiment, the second stacked structure 120 may be positioned in the pad area PA. For example, the second stacked structure 120 may be positioned on the lower side of the input/output pad 131. The second stacked structure 120 may include a plurality of second conductive layers 121 and a plurality of second insulating layers 122 that are alternately stacked in the vertical direction. For example, the plurality of second conductive layers 121 and the plurality of second insulating layers 122 may extend in the horizontal direction. The second conductive layers 121 may include a conductive material. For example, the second conductive layers 121 may include at least any one of a doped semiconductor (e.g., doped silicon), a conductive metal (e.g., tungsten, copper, molybdenum, and/or aluminum), a conductive metal nitride (e.g., titanium nitride and/or tantalum nitride), or a transition metal (e.g. titanium and/or tantalum). However, these are merely examples, and the material of the second conductive layers 121 is not limited thereto. Each of the plurality of second insulating layers 122 may be positioned between two adjacent second conductive layers 121. The second insulating layers 122 may include an insulating material. For example, the second insulating layers 122 may include at least any one of silicon oxide, silicon nitride, or silicon oxynitride. However, these are merely examples, and the material of the second insulating layers 122 is not limited thereto.

In an embodiment, the second stacked structure 120 may include a plurality of cell stacks ST2 and ST3 that are vertically stacked. Each of the cell stacks ST2 and ST3 included in the second stacked structure 120 may include a plurality of second conductive layers 121 and a plurality of second insulating layers 122. The second stacked structure 120 may include fewer cell stacks than the first stacked structure 110. For example, the second stacked structure 120 may include only some cell stacks ST2 and ST3 among the plurality of cell stacks ST1, ST2, and ST3 included in the first stacked structure 110. For example, the first stacked structure 110 and the second stacked structure 120 may be manufactured simultaneously by the same process. For example, the corresponding cell stacks ST2 and ST3 in the first stacked structure 110 and the second stacked structure 120 may be manufactured simultaneously by the same process. For example, the process for manufacturing the first cell stack ST1 may be performed only in the cell array area CA and the extension area EA, but not in the pad area PA, and the process for manufacturing the second cell stack ST2 and the third cell stack ST3 may be performed in all of the cell array area CA, the extension area EA, and the pad area PA. For example, a mold structure (not shown) may be positioned between the first stacked structure 110 and the second stacked structure 120. For example, the first stacked structure 110 and the second stacked structure 120 may be electrically separated by the mold structure (not shown) positioned therebetween. However, this is merely an example, and the second stacked structure 120 may be formed integrally with the first stacked structure 110. For example, the first conductive layers 111 and the second conductive layers 121 may be substantially an integral conductive layer, and the first insulating layers 112 and the second insulating layers 122 may be substantially an integral insulating layer. Alternatively, the first stacked structure 110 and the second stacked structure 120 may each be manufactured by a separate process. For example, the first stacked structure 110 and the second stacked structure 120 may be positioned separately from each other. Meanwhile, the drawings show the first stacked structure 110 includes three cell stacks ST1, ST2, and ST3 and the second stacked structure 120 includes two cell stacks ST2 and ST3. However, this is merely for ease of description, and the number of cell stacks included in the first stacked structure 110 and/or the second stacked structure 120 is not limited thereto.

In an embodiment, the mold insulator 132 may be positioned between the input/output pad 131 and the second stacked structure 120 in the pad area PA. The input/output pad 131 and the second stacked structure 120 may be positioned to be vertically spaced apart from each other by the mold insulator 132. For example, the upper end of the second stacked structure 120 may be positioned lower than the upper end of the first stacked structure 110. For example, the mold insulator 132 may be positioned at a height corresponding to some cell stacks (e.g., ST1) positioned in the upper portion of the first stacked structure 110. For example, the molded insulator 132 may be an insulator portion left by performing the process for some cell stack (e.g., ST1) only in the cell array area CA and the extension area EA, but not in the pad area PA.

In an embodiment, the plurality of through wiring structures 123 may be formed to penetrate at least a portion of the second stacked structure 120 in the pad area PA. The plurality of through wiring structures 123 may be electrically connected to the plurality of second conductive layers 121, respectively, in the pad area PA. For example, each of the through wiring structures 123 may penetrate at least a portion of the second stacked structure 120 to the height of a corresponding second conductive layer 121. For example, the plurality of through wiring structures 123 may penetrate at least a portion of the second stacked structure 120 while forming a staircase shape. For example, based on FIG. 5, the plurality of through wiring structures 123 may penetrate at least a portion of the second stacked structure 120 upward from the lower end of the second stacked structure 120. However, this is merely an example, and the plurality of through wiring structures 123 may penetrate at least a portion of the second stacked structure 120 downward from the upper end of the second stacked structure 120. The plurality of through wiring structures 123 may be electrically connected to the first semiconductor substrate 101 and/or the second semiconductor substrate 102 through wires and/or pads. The second stacked structure 120 and the plurality of through wiring structures 123 may be configured to function as at least any one of capacitors, resistors, and connection wires. For example, the second stacked structure 120 and the plurality of through wiring structures 123 may function as a circuit including at least any one of a capacitor, a resistor, and a connection wire. For example, the capacitor, the resistor, and/or the connection wire formed by the second stacked structure 120 and the plurality of through wiring structures 123 may be used to stabilize or control an internal voltage. This will be further described below.

In an embodiment, the semiconductor device 10 may include a cell array structure CS and a peripheral circuit structure PS. The cell array structure CS may include the first semiconductor substrate 101, the first stacked structure 110, the second stacked structure 120, the mold insulator 132, and a first insulating structure 141. For example, the first stacked structure 110, the second stacked structure 120, and the mold insulator 132 may be stacked on the first semiconductor substrate 101. For example, the first insulating structure 141 may be stacked on the first stacked structure 110 and the second stacked structure 120. Based on FIG. 5, the first stacked structure 110, the second stacked structure 120, and the mold insulator 132 may be positioned on the lower side of the first semiconductor substrate 101, and the first insulating structure 141 may be positioned on the lower sides of the first stacked structure 110 and the second stacked structure 120. A first bonding pad 142 may be positioned in the first insulating structure 141.

In an embodiment, the peripheral circuit structure PS may include the second semiconductor substrate 102 and a second insulating structure 151. The second insulating structure 151 may be stacked on the second semiconductor substrate 102. A second bonding pad 152 may be positioned in the second insulating structure 151. Based on FIG. 5, the peripheral circuit structure PS may be positioned at the lower end of the cell array structure CS. The peripheral circuit structure PS may be electrically connected to the cell array structure CS through the first bonding pad 142 and the second bonding pad 152. For example, based on FIG. 5, the upper end of the peripheral circuit structure PS and the lower end of the cell array structure CS may be electrically connected to each other through the first bonding pad 142 and the second bonding pad 152. However, this is merely an example, and the structure of the cell array structure CS and/or the structure of the peripheral circuit structure PS are not limited thereto.

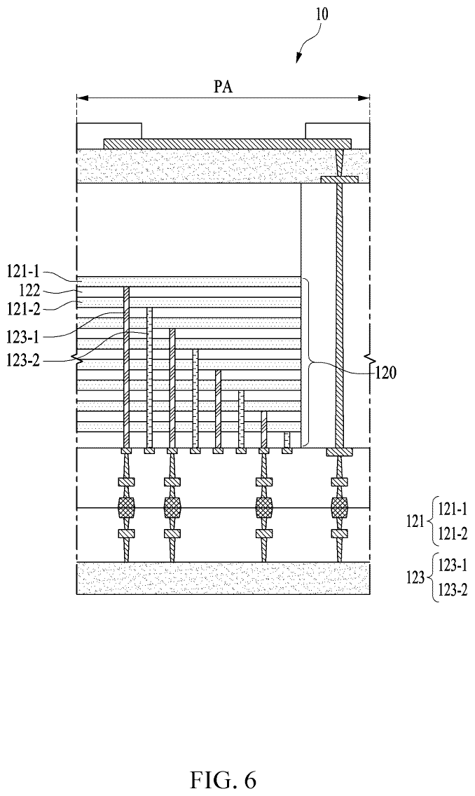

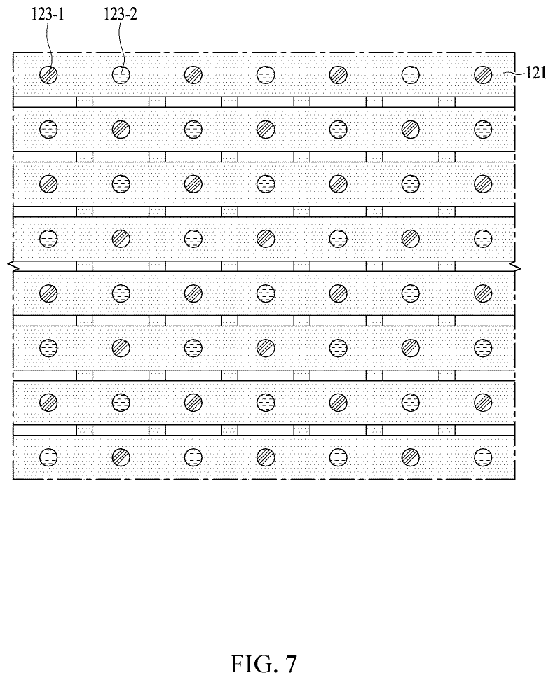

FIG. 6 is a schematic cross-sectional view of the pad area PA of the semiconductor device 10 according to an embodiment. FIG. 7 is a schematic plan view illustrating an arrangement of the plurality of through wiring structures 123 in the pad area PA of the semiconductor device 10 according to an embodiment. FIGS. 6 and 7 are schematically illustrated for ease of description and do not limit the structure of the semiconductor device 10.

Referring to FIGS. 6 and 7, in an embodiment, the plurality of through wiring structures 123 may include one or more first through wiring structures 123-1 and one or more second through wiring structures 123-2. A first through wiring structure 123-1 may be connected to any one second conductive layer 121-1 among the plurality of second conductive layers 121, and a second through wiring structure 123-2 may be connected to another second conductive layer 121-2 among the plurality of second conductive layers 121. Hereinafter, for ease of description, any one second conductive layer 121-1 to which a first through wiring structure 123-1 is connected will be referred to as a first connection conductive layer 121-1, and another second conductive layer 121-2 to which the first through wiring structure 123-1 is connected will be referred to as a second connection conductive layer 121-2. Additionally, for ease of description in FIGS. 6 and 7, the first through wiring structures 123-1 and the second through wiring structures 123-2 are shown with different hatchings.

In an embodiment, a first connection conductive layer 121-1 and a second connection conductive layer 121-2 may be second conductive layers 121 positioned adjacent to each other. For example, one second insulating layer 122 may be positioned between the first connection conductive layer 121-1 and the second connection conductive layer 121-2. When a first through wiring structure 123-1 and a second through wiring structure 123-2 are electrically connected to each other, the first connection conductive layer 121-1, the second connection conductive layer 121-2, and the second insulating layer 122 positioned therebetween may substantially function as a single capacitor. For example, the first connection conductive layer 121-1 connected to the first through wiring structure 123-1 may substantially function as any one pole, the second connection conductive layer 121-2 connected to the second through wiring structure 123-2 may substantially function as another pole, and the second insulating layer 122 positioned therebetween may substantially function as a dielectric.

In an embodiment, the first through wiring structures 123-1 and the second through wiring structures 123-2 may be arranged repeatedly. For example, the first through wiring structures 123-1 and the second through wiring structures 123-2 may be alternately arranged in the horizontal direction. For example, as shown in FIG. 6, the first through wiring structures 123-1 and the second through wiring structures 123-2 may be alternately arranged in a horizontal direction. For example, as shown in FIG. 7, the first through wiring structures 123-1 and the second through wiring structures 123-2 may be arranged in a grid pattern.

According to the arrangements shown in FIGS. 6 and 7, a corresponding first connection conductive layer 121-1, second connection conductive layer 121-2, and second insulating layer 122 positioned therebetween may function as a capacitor for each first through wiring structure 123-1 and second through wiring structure 123-2 positioned adjacent. For example, the second stacked structure 120 and the plurality of through wiring structures 123 may function as a circuit including a plurality of capacitors. However, this is merely an example, and the arrangement of the first through wiring structures 123-1 and the second through wiring structures 123-2 is not limited thereto. For example, the first through wiring structures 123-1 and/or the second through wiring structures 123-2 may be omitted or added in some positions.

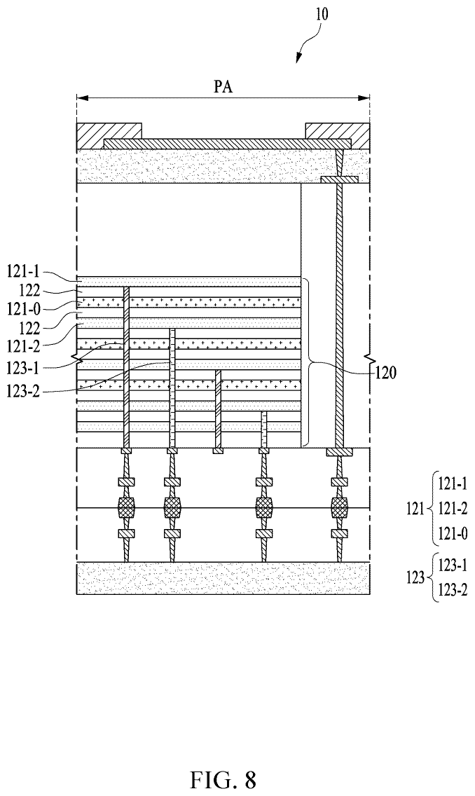

FIG. 8 is a schematic cross-sectional view of the pad area PA of the semiconductor device 10 according to an embodiment. FIG. 8 is schematically illustrated for ease of description and does not limit the structure of the semiconductor device 10.

Referring to FIG. 8, in an embodiment, the plurality of through wiring structures 123 may include one or more first through wiring structures 123-1 and one or more second through wiring structures 123-2. A first through wiring structure 123-1 may be connected to any one second conductive layer 121-1 among the plurality of second conductive layers 121, and a second through wiring structure 123-2 may be connected to another second conductive layer 121-2 among the plurality of second conductive layers 121. Hereinafter, for ease of description, any one second conductive layer 121-1 to which a first through wiring structure 123-1 is connected will be referred to as a first connection conductive layer 121-1, and another second conductive layer 121-2 to which the first through wiring structure 123-1 is connected will be referred to as a second connection conductive layer 121-2. Additionally, for ease of description in FIG. 8, the first through wiring structures 123-1 and the second through wiring structures 123-2 are shown with different hatchings.

In an embodiment, one or more second conductive layers 121-0 and two or more second insulating layers 122 may be positioned between a first connection conductive layer 121-1 and a second connection conductive layer 121-2. The one or more second conductive layers 121-0 positioned between the first connection conductive layer 121-1 and the second connection conductive layer 121-2 may be configured such that a current does not flow therethrough. When a first through wiring structure 123-1 and a second through wiring structure 123-2 are electrically connected to each other, the first connection conductive layer 121-1, the second connection conductive layer 121-2, and the one or more second conductive layers 121-0 and two or more second insulating layers 122 positioned therebetween may substantially function as a single capacitor. For example, the first connection conductive layer 121-1 connected to the first through wiring structure 123-1 may substantially function as any one pole, the second connection conductive layer 121-2 connected to the second through wiring structure 123-2 may substantially function as another pole, and the one or more second conductive layers 121-0 and two or more second insulating layers 122 positioned therebetween may substantially function as a dielectric. This structure may implement a capacitor with a larger capacity than the capacitor implemented in the embodiment shown in FIG. 6. Meanwhile, the embodiment shown in FIG. 8 is a representative drawing to help better understanding, and the embodiment for changing the capacity of the capacitor is not limited to the structure of FIG. 8. For example, increasing the numbers of second conductive layers 121-0 and/or second insulating layers 122 positioned between the first connection conductive layer 121-1 and the second connection conductive layer 121-2 may further increase the capacity of the capacitor. For example, capacitors with various capacities may also be implemented as well in the structure of the embodiment shown in FIG. 6. For example, in the embodiment shown in FIG. 6, the capacity of a corresponding capacitor may be determined variously depending on which two through wiring structures 123 among the plurality of through wiring structures 123 are connected. Additionally, the embodiments shown in FIGS. 6 and 8 may be configured in combination with each other.

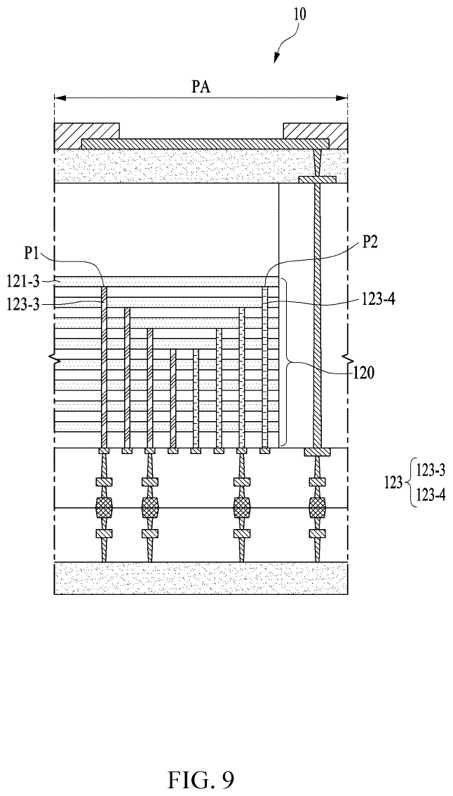

FIG. 9 is a schematic cross-sectional view of the pad area PA of the semiconductor device 10 according to an embodiment. FIG. 9 is schematically illustrated for ease of description and does not limit the structure of a semiconductor device 10.

Referring to FIG. 9, in an embodiment, the plurality of through wiring structures 123 may include one or more third through wiring structures 123-3 and one or more fourth through wiring structures 123-4. A third through wiring structure 123-3 and a fourth through wiring structure 123-4 may be connected to the same second conductive layer 121-3. For example, the third through wiring structure 123-3 and the fourth through wiring structure 123-4 may be connected to any one second conductive layer 121-3 of the plurality of second conductive layers 121. Hereinafter, for ease of description, any one second conductive layer 121-1 to which a third through wiring structure 123-3 and a fourth through wiring structure 123-4 are connected will be referred to as a third connection conductive layer 121-3. Additionally, for ease of description in FIG. 9, the third through wiring structures 123-3 and the fourth through wiring structures 123-4 are shown with different hatchings.

In an embodiment, the third through wiring structure 123-3 and the fourth through wiring structure 123-4 may each be connected to the third connection conductive layer 121-3 at different positions. For example, the third through wiring structure 123-3 may be connected to a first position P1 of the third connection conductive layer 121-3, and the fourth through wiring structure 123-4 may be connected to a second position P2 of the third connection conductive layer 121-3. When the third through wiring structure 123-3 and the fourth through wiring structure 123-4 are electrically connected to each other, the third connection conductive layer 121-3 between the first position P1 and the second position P2 may function as a resistor and/or a connection wire. The size of a corresponding resistor may be adjusted depending on the distance between the first position P1 and the second position P2. For example, when the distance between the first position P1 and the second position P2 increases, the size of the corresponding resistor may increase. For example, the third through wiring structures 123-3 and the fourth through wiring structures 123-4 may be arranged at various intervals to implement resistors of various sizes. Meanwhile, FIGS. 6 to 9 are exemplarily illustrated for ease of description, and the arrangement of the first through wiring structures 123-1, the second through wiring structures 123-2, the third through wiring structures 123-3, and the fourth through wiring structures 123-4 is not limited to those shown in the drawings. For example, the embodiments shown in FIGS. 6 to 9 may be configured in combination with each other. For example, the first through wiring structures 123-1, the second through wiring structures 123-2, the third through wiring structures 123-3, and the fourth through wiring structures 123-4 may be combined and/or arranged in various manners to implement capacitors and/or resistors of various sizes.

In an embodiment, according to the structures of the semiconductor device 10 described with reference to FIGS. 5 to 9, it is possible to form the second stacked structure 120 and the plurality of through wiring structures 123 in a space under the input/output pad 131 and utilize the second stacked structure 120 and the plurality of through wiring structures 123 as capacitors, resistors, and/or wires, thereby improving the space efficiency of the semiconductor device 10. In addition, by arranging the second stacked structure 120 and/or the plurality of through wiring structures 123 to be vertically spaced from the input/output pad 131, it is possible to reduce pressure and/or heat applied to the second stacked structure 120 and/or the plurality of through wiring structures 123 in the process of connecting a test electrode and/or a connection structure (e.g., the connection structure 2400 of FIG. 3 and the connection structure 2400 of FIG. 4) to the input/output pad 131. Therefore, in the process of connecting the test electrode and/or the connection structure 2400 to the input/output pad 131, it is possible to reduce damage to the second stacked structure 120 and/or the plurality of through wiring structures 123. Since the second stacked structure 120 and the first stacked structure 110 may be manufactured simultaneously, a separate additional process may not be required.

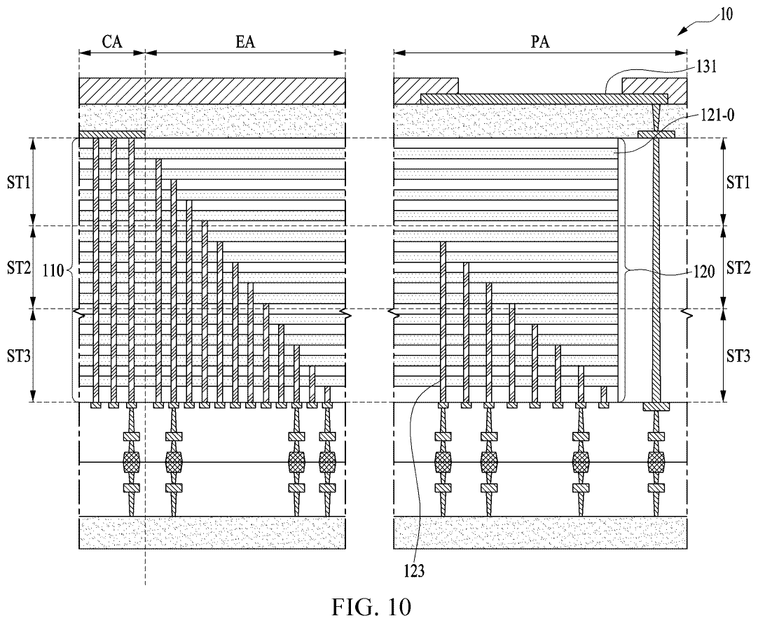

FIG. 10 is a schematic cross-sectional view of a semiconductor device according to an embodiment. FIG. 10 is schematically illustrated for ease of description and does not limit the structure of the semiconductor device 10.

Referring to FIG. 10, in the semiconductor device 10 according to an embodiment, the second stacked structure 120 and the first stacked structure 110 may include the same cell stacks ST1, ST2, and ST3. The through wiring structures 123 may not be formed in the upper area of the second stacked structure 120 positioned adjacent to the input/output pad 131. For example, the through wiring structures 123 may not be formed in all or part of some cell stacks (e.g., ST1) positioned adjacent to the input/output pad 131, but only in the remaining cell stacks (e.g., ST2 and ST3). For example, the second conductive layers 121-0 to which the through wiring structures 123 are not connected may be understood as dummy layers that are not in use. Since even this structure may cause the plurality of through wiring structures 123 to be vertically spaced from the input/output pad 131, the same effects and/or advantages as those of the semiconductor device 10 described with reference to FIGS. 5 to 9 may be achieved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

A number of embodiments have been described above. Nevertheless, it should be understood that various modifications and variations may be made to these embodiments. For example, suitable results may be achieved if the described techniques are performed in a different order, and/or if components in a described system, architecture, device, or circuit are combined in a different manner, and/or replaced or supplemented by other components or their equivalents.

Accordingly, other implementations are within the scope of the following claims.

What is claimed is:

1. A semiconductor device comprising:
a semiconductor substrate including a cell array area, an extension area, and a pad area;
a first stacked structure on the cell array area and the extension area, the first stacked structure including a plurality of first conductive layers and a plurality of first insulating layers that are alternately stacked;
an input/output pad on an upper end portion of the pad area;
a second stacked structure on a lower side of the input/output pad, the second stacked structure including a plurality of second conductive layers and a plurality of second insulating layers alternately stacked on the pad area;
a plurality of through wiring structures respectively connected to the plurality of second conductive layers on the pad area; and
a mold insulator between the input/output pad and the second stacked structure such that the input/output pad and the second stacked structure are vertically spaced apart from each other.

2. The semiconductor device of claim 1, wherein an upper end of the second stacked structure is lower than an upper end of the first stacked structure.

3. The semiconductor device of claim 1, wherein the second stacked structure and the plurality of through wiring structures are configured to function as at least one of capacitors, resistors, or connection wires.

4. The semiconductor device of claim 3, wherein the plurality of through wiring structures comprise:
a first through wiring structure connected to a first one of the plurality of second conductive layers; and
a second through wiring structure connected to a second one of the plurality of second conductive layers.

5. The semiconductor device of claim 4, wherein
a single capacitor includes the first one of the plurality of second conductive layers, the second one of the plurality of second conductive layers, and one of the plurality of second insulating layers therebetween.

6. The semiconductor device of claim 4, wherein
one or more of the plurality of second conductive layers and two or more of the plurality of second insulating layers are between the first one of the plurality of second conductive layers and the second one of the plurality of second conductive layers,
the one or more of the plurality of second conductive layers and the second one of the plurality of second conductive layers are configured so that electricity does not flow therethrough, and
the first one of the plurality of second conductive layers, the second one of the plurality of second conductive layers, and the one or more of the plurality of the second conductive layers and the two or more second insulating layers are configured to function as a single capacitor.

7. The semiconductor device of claim 4, wherein the first through wiring structure and the second through wiring structure are alternately arranged in a horizontal direction.

8. The semiconductor device of claim 3, wherein the plurality of through wiring structures further comprise:
a first through wiring structure connected to a first one of the plurality of second conductive layers; and
a second through wiring structure connected to a second one of the plurality of second conductive layers, wherein
the first one of the plurality of second conductive layers is configured to function as a resistor or a connection wire.

9. The semiconductor device of claim 1, further comprising:
a connection structure connected to the input/output pad, wherein
the connection structure is configured for being electrically connected to a package substrate.

10. The semiconductor device of claim 1, wherein the first conductive layers are word lines or bit lines.

11. The semiconductor device of claim 1, wherein the first stacked structure and the second stacked structure are manufactured simultaneously by a same process.

12. The semiconductor device of claim 1, comprising:
a cell array structure comprising the first stacked structure and the second stacked structure; and
a peripheral circuit structure positioned at a lower end of the cell array structure and electrically connected to the cell array structure through a bonding pad.

13. The semiconductor device of claim 12, wherein the input/output pad is at an upper end of the cell array structure.

14. The semiconductor device of claim 13, further comprising:
an input/output contact structure penetrating the cell array structure, wherein
the input/output contact structure electrically connects the input/output pad and the peripheral circuit structure.

15. The semiconductor device of claim 1, further comprising:
a plurality of channel structures penetrating the first stacked structure in the cell array area; and
a plurality of cell contact plugs respectively connected to the plurality of first conductive layers in the extension area.

16. An electronic system comprising:
a package substrate;
a semiconductor device on the package substrate; and
a connection structure electrically connecting the package substrate and the semiconductor device, wherein
the semiconductor device includes
a semiconductor substrate including a cell array area, an extension area, and a pad area,
a first stacked structure on the cell array area and the extension area, the first stacked structure including a plurality of first conductive layers and a plurality of first insulating layers that are alternately stacked,
an input/output pad on an upper end portion of the pad area and electrically connected to the package substrate through the connection structure,
a second stacked structure on a lower side of the input/output pad, the second stacked structure including a plurality of second conductive layers and a plurality of second insulating layers alternately stacked,
a plurality of through wiring structures respectively connected to the plurality of second conductive layers on the pad area, and
a mold insulator between the input/output pad and the second stacked structure such that the input/output pad and the second stacked structure are vertically spaced apart from each other.

17. The electronic system of claim 16, wherein an upper end of the second stacked structure is lower than an upper end of the first stacked structure.

18. The electronic system of claim 16, wherein the second stacked structure and the plurality of through wiring structures are configured to function as at least one of capacitors, resistors, or connection wires.

19. The electronic system of claim 16, wherein the first conductive layers are word lines or bit lines.

20. The electronic system of claim 16, wherein the first stacked structure and the second stacked structure are manufactured simultaneously by a same process.
